(19) United States
(12) Patent Application Publication
(10) Pub. No.: US 2008/0185737 A1
(43) Pub. Date: Aug. 7, 2008

(54) INTEGRATED CIRCUIT SYSTEM WITH PRE-CONFIGURED BOND WIRE BALL

(76) Inventor: Pandi Chelvam Marimuthu, Singapore (SG)

Correspondence Address: LAW OFFICES OF MIKIO ISHIMARU, 333 W. EL CAMINO REAL, SUITE 330, SUNNYVALE, CA, 94087, US

(21) Appl. No.: 12/024,470

(22) Filed: Feb. 1, 2008

Related U.S. Application Data
(60) Provisional application No. 60/888,064, filed on Feb. 2, 2007.

(51) Int. Cl. H01L 23/49; B23K 1/00

(52) U.S. Cl. 257/780; 228/19; 257/E23.025

(57) ABSTRACT

An integrated circuit system is provided including forming a wire ball on a bond wire; forming a shaped ball from the wire ball; and attaching the shaped ball on an integrated circuit die.

### CROSS-REFERENCE TO RELATED APPLICATION

This application claims the benefit of U.S. Provisional Patent Application Ser. No. 60/888,064 filed Feb. 2, 2007.

### TECHNICAL FIELD

The present disclosure relates generally to semiconductor technology, and more particularly to a system for bond wires.

### BACKGROUND ART

Micro devices and micro-circuits have come into use in a wide variety of consumer, commercial, industrial, and military devices and equipment. Micro-circuits, such as integrated circuits, contain a large number of active circuit elements, such as transistors, and passive elements, such as resistors and capacitors, mounted on a substrate. Semiconductor integrated circuits consist of small monolithic chips made of a semiconducting material, such as silicon, having discrete areas into which impurities are diffused to form circuit elements and having conductive paths between circuit elements on the chip formed by selectively etching metallized layers of the chip. In hybrid micro-circuits, circuit elements mounted on a ceramic substrate are usually interconnected by conductive ink paths on the substrate.

Functional portions of integrated circuits are typically in the form of very small, rectangular-shaped chips. Input connections to integrated circuit chips are often made by wire bonding.

Wire bonding generally utilizes ultrasonic energy and/or heat to form an intermetallic bond or weld between the wire and bond site. Such wire bonds are used to form interconnections between conductive pads of an integrated circuit chip and terminals of a package used to enclose and protect the chip, and are also used to connect lead-out terminals to printed circuit boards.

Bonding wires used to interconnect the pads of an integrated circuit chip to terminals of a package containing the chip are generally made of aluminum or gold. Each bonding wire bonds to the upper surface of a small, typically rectangular-shaped, integrated circuit pad at one end of the wire to form a first bond site, and to another similarly shaped pad, or to a package terminal comprising a second bond site.

The most common method of interconnecting wires between bond sites, such as integrated circuit chip pads and/or external terminals, uses ultrasonic energy to form a welded bond at each end of a conducting wire. To form such bonds, a free end of a length of bonding wire protruding from the tip of a tapered pencil-shaped bonding tool is placed in contact with a pad. The tool tip is then pressed against the wire, and energized with ultrasonic energy supplied by an ultrasonic transducer for a short time interval.

The combination of a vertically directed downward pressure applied by the tool to the contact region between the lower surface of the wire and the upper surface of the pad, combined with an oscillatory scrubbing motion at an ultrasonic frequency of the tool tip, in a horizontal direction parallel to the pad, causes an inter-molecular diffusion bond, sometimes referred to as a “weld,” to be formed between the wire and pad.

The automated tool is then moved in an arc-shaped path to another bond site. Motion of the tool tip away from a first, “source” bond site to a second “destination” bond site causes wire supplied from a supply reel or spool to an upper entrance opening of a wire feed bore through the tool, to be withdrawn from a lower exit opening of the bore and form an arch-shaped interconnecting wire segment between the first and second bond sites. The tool is then moved downwardly to press a trailing portion of the wire segment against the second bond site, and the ultrasonic transducer once again energized to bond the trailing end of the wire to the second bond site. After the second or last bond in a series of bonds has been thus formed, the wire is severed at the last bond site.

The integrated circuit chip is next environmentally sealed by use of a ceramic or an epoxy. Finally, the electrical leads that extend to the external portion of a package substrate or a lead frame are trimmed and prepared for connection to the package substrate or the printed circuit board so as to conduct electrical signals between the input and output terminals of the integrated circuit chip and the printed circuit board.

As the integrated circuit chip has become smaller and weaker ultra low dielectric constant dielectric materials become more common, the vertically directed downward pressure applied by the tool has been found to cause problems. The pressure squashes or crushes the contact pads resulting in distorting the pad resulting in poor wire bonding. In some wire bonds, there is damage to the integrated circuit chip, which renders it inoperative.

Thus, a need still remains for improved packaging methods, systems, and designs. In view of the shrinking size of consumer electronics and the demand for more sophisticated functions in the restricted space, it is increasingly critical that answers be found to these problems. In view of the ever-increasing commercial competitive pressures, increasing consumer expectations, and diminishing opportunities for meaningful product differentiation in the marketplace, it is increasingly critical that answers be found to these problems. Moreover, the ever-increasing need to save costs, improve efficiencies, and meet such competitive pressures adds even greater urgency to the critical necessity that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit system including forming a wire ball on a bond wire; forming a shaped ball from the wire ball; and attaching the shaped ball on an integrated circuit die.

Certain embodiments of the invention have other advantages in addition to or in place of those mentioned above. The advantages will become apparent to those skilled in the art from a reading of the following detailed description when taken with reference to the accompanying drawings.

### BRIEF DESCRIPTION OF THE DRAWINGS

FIG. 1 is a top plan view of an integrated circuit package system in an embodiment of the present invention;

FIG. 2 is a cross-sectional view of the integrated circuit package system along line 2-2 of FIG. 1;

FIG. 3 is a schematic view of a portion of a wire bonding system in a preparing step of the bond wire;

FIG. 4 is a schematic view of the portion of the wire bonding system in a ball shaping step of the bond wire;

FIG. 5 is a schematic view of the portion of the wire bonding system in a first attaching step of the bond wire;

FIG. 6 is a schematic view of the portion of the wire bonding system in a second attaching step of the bond wire;

FIGS. 7A, 7B, and 7C are more detailed schematic views of the wire bonding process;

FIGS. 8A, 8B, and 8C are schematic views of another wire bonding process in an embodiment of the present invention;

FIGS. 9A, 9B, and 9C are schematic views of yet another wire bonding process in an embodiment of the present invention; and

FIG. 10 is a flow chart of an integrated circuit package system for manufacturing of the integrated circuit package system in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that process or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

Likewise, the drawings showing embodiments of the system are semi-diagrammatic and not to scale and, particularly, some of the dimensions are for the clarity of presentation and are shown greatly exaggerated in the drawing FIGs. Generally, the invention can be operated in any orientation. The terms first, second, and third embodiments are used merely as a convenience and do not have any other significance.

For expository purposes, the term “horizontal” as used herein is defined as a plane parallel to the plane or surface of the package substrate, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means there is direct contact among elements. The term “system” means the method and the apparatus of the present invention, as appropriate and as evident from context. The term “processing” as used herein includes stamping, forging, patterning, exposure, development, etching, cleaning, and/or removal of the material or laser trimming as required in forming a described structure.

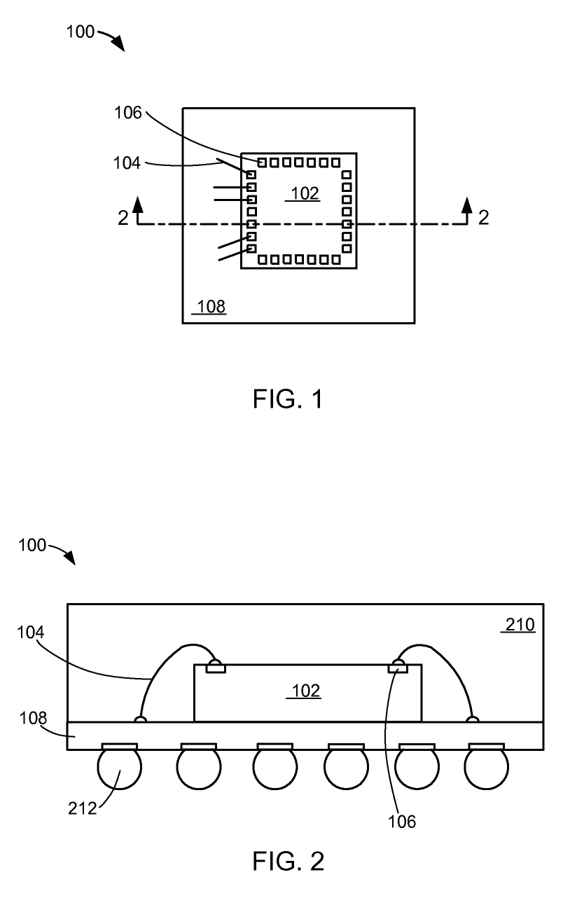

Referring now to FIG. 1, therein is shown a top plan view of an integrated circuit package system 100 in an embodiment of the present invention. The top plan view depicts the integrated circuit package system 100 without a top cover exposing an integrated circuit die 102. Wires 104, such as bond wires or ribbon bond wires, connect bond pads 106 of the integrated circuit die 102 and a carrier 108, such as a substrate. For clarity, not all the wires 104 are shown connecting the integrated circuit die 102 and the carrier 108.

Referring now to FIG. 2, therein is shown a cross-sectional view of the integrated circuit package system 100 along line 2-2 of FIG. 1. The cross-sectional view depicts the integrated circuit die 102 mounted over the carrier 108. The wires 104 connect between the bond pads 106 and the carrier 108. An encapsulation 210, such as a cover of epoxy molding compound, covers the integrated circuit die 102 and the wires 104 over the carrier 108. External interconnects 212, such as solder balls, can be optionally formed to the bottom of the carrier 108.

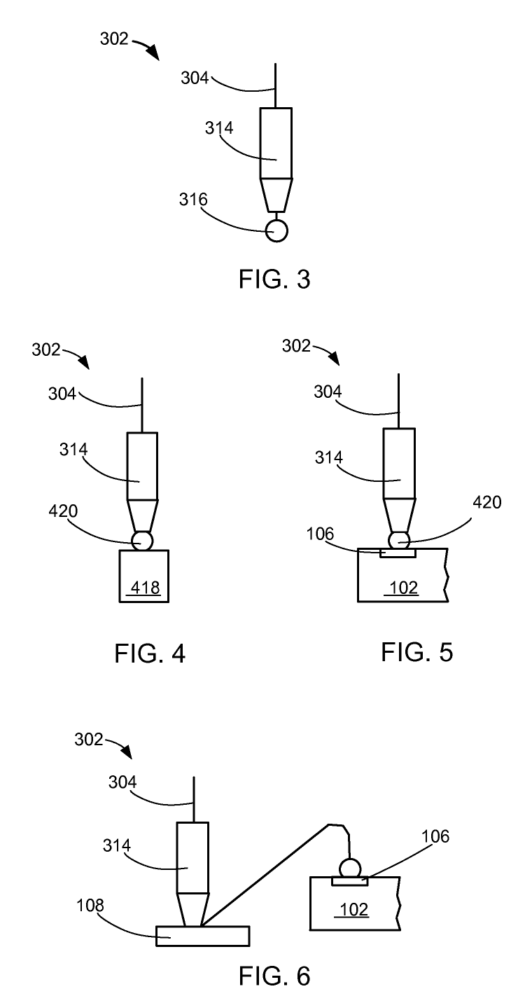

Referring now to FIG. 3, therein is shown a schematic view of a portion of a wire bonding system 302 in a preparing step of a bond wire 304. The portion of the wire bonding system 302 includes a capillary 314 for feeding and bonding the bond wire 304, such as a bond wire including gold, copper, silver, or other metals or metal alloys. In preparation of the wire bonding of the integrated circuit die 102 of FIG. 1, an electrical spark, commonly referred to as electrical flaming-off (EFO), can create a wire ball 316, commonly referred to as free-air ball (FAB), at the end of the bond wire 304 at the tip of the capillary 314.

Referring now to FIG. 4, therein is shown a schematic view of the portion of the wire bonding system 302 in a ball shaping step of the bond wire 304. The wire ball 316 of FIG. 3 is shaped by a shaping tool 418 forming a shaped ball 420 at the end of the bond wire 304. The shaping tool 418 is temperature controlled for shaping the wire ball 316 to the shaped ball 420. The temperature of the shaping tool 418 can depend on a number of factors, such as the material of the bond wire 304. The temperature can be varied in the shaping process.

The wire bonding system 302 may be configured in a number of ways with the shaping tool 418. For example, the capillary 314 can be moved to the shaping tool 418 or the shaping tool 418 can be moved to the capillary 314. As another example, the wire bonding system 302 may include a bank (not shown) of different types of the shaping tool 418. Preferably, the shaping tool 418 can be integrated with a bond head (not shown) in the wire bonding system 302.

For illustrative purposes, the wire bonding system 302 forms the shaped ball 420 from the wire ball 316 in one application of the shaping tool 418, although it is understood that the wire bonding system 302 can apply the shaping tool differently. For example, the wire bonding system 302 can apply the shaping tool 418 and the capillary 314 in a number of times to form different geometrical shapes with the wire ball 316, such as multiple-ball stack.

Referring now to FIG. 5, therein is shown a schematic view of the portion of the wire bonding system 302 in a first attaching step of the bond wire 304. The capillary 314 can be placed over one of the bond pads 106 of the integrated circuit die 102. The capillary 314 can be lowered towards the integrated circuit die 102 such that the shaped ball 420 contacts one of the bond pads 106. The shaped ball 420 is attached to the bond pads 106 with a welding process, with ultrasonic welding. The impact force on the bond pads 106 can be reduced to zero with shaped ball 420 are preconfigured to have a flat surface (at the bottom) that can be readily bonded to the bond pads 420.

It has been discovered that the present invention eliminates reliability issues associated with deformation of bond pad, such as cratering, peeling by shaping the ball at the end of the capillary before attaching to the bond pads of the integrated circuit die. The preconfigured or shaped balls reduces the impact force of the capillary and the wire ball onto the bond pads to shape wire ball, thereby improving reliability by reducing impact force damage on the bond pads. As a more specific example, the preconfigured ball formed with the shaping tool eliminates crater in gold ball bonding on the bond pads for normal, low-K, or ultra-low-K devices. This allows use of copper bond wires to be used for normal, low-K, or ultra-low-K devices, where the inter-layer dielectric strength is lower. The preconfigured ball also lowers cost by eliminating the need of thicker bond pads. For example, the thickness of the bond pads can remain at contemporary level of 0.6 to 1.2 μm.

Referring now to FIG. 6, therein is shown a schematic view of the portion of the wire bonding system 302 in a second attaching step of the bond wire 304. With the bond wire 304 attached with the one of the bond pads 106 of the integrated circuit die 102, the capillary 314 is position over the carrier 108 attaching the bond wire 304 with the carrier 108. The capillary 314 cuts the bond wire 304 for attachment with the carrier 108 forming the wires 104 of FIG. 2 between the carrier 108 and the integrated circuit die 102.

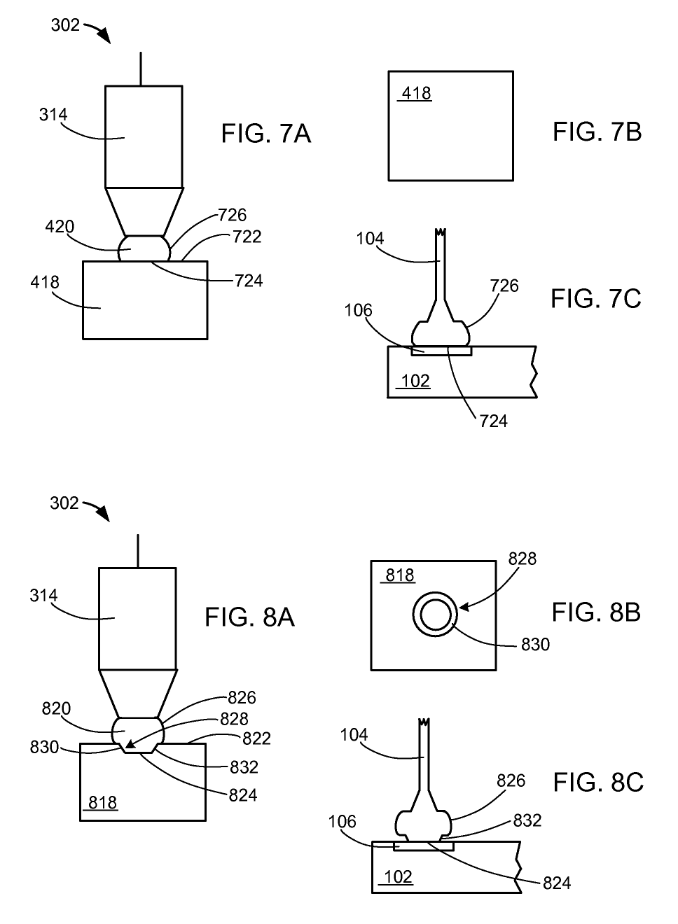

Referring now to FIGS. 7A, 7B, and 7C, therein are shown more detailed schematic views of the wire bonding process. In FIG. 7A, therein is shown a cross-sectional view of the portion of the wire bonding system 302 with capillary 314 over the shaping tool 418. The wire ball 316 of FIG. 4 is preferably in contact with the shaping tool 418 forming the shaped ball 420. A top side 722 of the shaping tool 418 is planar. The shaped ball 420 includes a planar portion 724 at the bottom portion of the shaped ball 420 formed with the shaping tool 418. The shaped ball 420 also includes a curved portion 726 continuing from the planar portion 724. In FIG. 7B, therein is shown a top schematic view of the shaping tool 418.

In FIG. 7C, therein is shown a cross-sectional view of a portion of the wires 104 bonded with one of the bond pads 106. The wires 104 include the planar portion 724 and the curved portion 726 over one of the bond pads 106. The shaped ball 420 is preferably in contact with one of the bond pads 106 of the integrated circuit die 102.

Referring now to FIGS. 8A, 8B, and 8C, therein are shown schematic views of another wire bonding process in an embodiment of the present invention. In FIG. 8A, therein is shown a cross-sectional view of the portion of the wire bonding system 302 with the capillary 314 over a shaping tool 818. A top side 822 of the shaping tool 818 includes a recess 828. The wire ball 316 of FIG. 4 extends over sides 830 of the recess 828 for forming a shaped ball 820. The shaped ball 820 includes a planar portion 824 at the bottom portion of the shaped ball 820 formed with the shaping tool 818. The shaped ball 820 also includes a curved portion 826 continuing from the planar portion 824. The shaped ball 820 further includes a stepped portion 832 between the planar portion 824 and the curved portion 826.

In FIG. 8B, therein is shown a top schematic view of the shaping tool 818. The top schematic view depicts the recess 828 having a bottom of the recess 828 and the sides 830 of the recess 828. For illustrative purposes, the recess 828 is shown in a concentric circle geometrical configuration, although it is understood that the recess 828 can be formed in a different geometric configuration. For example, the recess 828 can be other geometric shapes, such as rectangular. As another example, the recess 828 can be deeper such that the radius of the bottom and the sides 830 may differ to a greater extent.

In FIG. 8C, therein is shown a cross-sectional view of a portion of the wires 104 bonded with one of the bond pads 106. The wires 104 include the planar portion 824, the stepped portion 832, and the curved portion 826 over one of the bond pads 106.

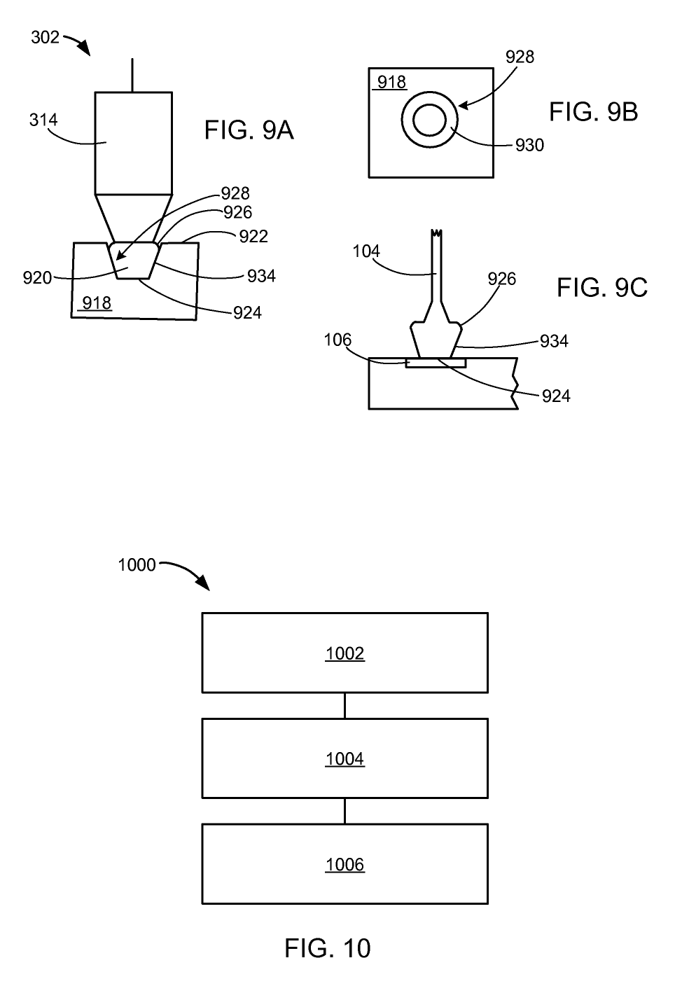

Referring now to FIGS. 9A, 9B, and 9C, therein are shown schematic views of yet another wire bonding process in an embodiment of the present invention. In FIG. 9A, therein is shown a cross-sectional view of the portion of the wire bonding system 302 with the capillary 314 over a shaping tool 918. A top side 922 of the shaping tool 918 includes a recess 928. The wire ball 316 of FIG. 4 is within the recess 928 for forming a shaped ball 920. The shaped ball 920 includes a planar portion 924 at the bottom portion of the shaped ball 920 formed with the shaping tool 918. The shaped ball 920 also includes a curved portion 926 continuing from the planar portion 924. The shaped ball 920 further includes a sloped portion 934 between the planar portion 924 and the curved portion 926.

In FIG. 9B, therein is shown a top schematic view of the shaping tool 918. The top schematic view depicts the recess 928 having a bottom of the recess 928 and sides 930 of the recess 928. For illustrative purposes, the recess 928 is shown in a concentric circle geometrical configuration, although it is understood that the recess 928 can be formed in a different geometric configuration. For example, the recess 928 can be other geometric shapes, such as rectangular.

In FIG. 9C, therein is shown a cross-sectional view of a portion of the wires 104 bonded with one of the bond pads 106. The wires 104 include the planar portion 924, the sloped portion 934, and the curved portion 926 over one of the bond pads 106.

For illustrative purposes, the shaping tool 918 is shown with the recess 928, although it is understood that the shaping tool 918 can have a different configuration. For example, the shaping tool 918 can have a number of recesses of different size and shapes as well as the planar surface as shown in FIG. 7A.

Referring now to FIG. 10, therein is shown a flow chart of an integrated circuit package system 1000 for manufacturing of the integrated circuit package system 100 in an embodiment of the present invention. The system 1000 includes forming a wire ball on a bond wire in a block 1002; forming a shaped ball from the wire ball in a block 1004; and attaching the shaped ball on an integrated circuit die in a block 1006.

These and other valuable aspects of the present invention consequently further the state of the technology to at least the next level.

Thus, it has been discovered that the integrated circuit package system of the present invention furnishes important and heretofore unknown and unavailable solutions, capabilities, and functional aspects for developing and manufacturing wire bonded package solutions. The resulting processes and configurations are straightforward, cost-effective, uncomplicated, highly versatile, and effective, can be surprisingly and unobviously implemented by adapting known technologies, and are thus readily suited for efficiently and economically manufacturing package devices fully compatible with conventional manufacturing processes and technologies. The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. An integrated circuit system comprising:
forming a wire ball on a bond wire;
forming a shaped ball from the wire ball; and
attaching the shaped ball on an integrated circuit die.

2. The system as claimed in claim 1 wherein forming the shaped ball from the wire ball includes shaping the wire ball on a shaping tool.

3. The system as claimed in claim 1 wherein attaching the shaped ball on the integrated circuit die includes attaching the shaped ball with a bond pad of the integrated circuit die.

4. The system as claimed in claim 1 wherein forming the shaped ball from the wire ball includes shaping the wire ball in a recess of a shaping tool.

5. The system as claimed in claim 1 wherein forming the shaped ball from the wire ball includes forming the shaped ball without contacting the integrated circuit die.

6. An integrated circuit system comprising:
forming a wire ball on a bond wire;
forming a shaped ball from the wire ball with a shaping tool; and
attaching the shaped ball on a bond pad of an integrated circuit die.

7. The system as claimed in claim 6 wherein forming the shaped ball from the wire ball with the shaping tool includes pressing the wire ball on the shaping tool.

8. The system as claimed in claim 6 wherein forming the shaped ball from the wire ball with the shaping tool includes placing the wire ball in a recess of the shaping tool with the wire ball over a side of the recess.

9. The system as claimed in claim 6 wherein forming the shaped ball from the wire ball with the shaping tool includes placing the wire ball within a recess of the shaping tool.

10. The system as claimed in claim 6 wherein forming the shaped ball from the wire ball with the shaping tool includes shaping the wire ball with multiple applications of the shaping tool.

11. An integrated circuit system comprising:
a carrier;
an integrated circuit die having a bond pad over the carrier; and
a wire having a shaped ball between the carrier and the integrated circuit die with the shaped ball on the bond pad and the bond pad devoid of a crater.

12. The system as claimed in claim 11 wherein the wire is a copper bond wire.

13. The system as claimed in claim 11 wherein the wire is a gold bond wire.

14. The system as claimed in claim 11 wherein the wire having the shaped ball includes the shaped ball having a planar portion and a curved portion.

15. The system as claimed in claim 11 further comprising an encapsulation over the integrated circuit die, the wire, and the carrier.

16. The system as claimed in claim 11 wherein the wire having the shaped ball includes the shaped ball having a planar portion and a curved portion with a stepped portion between the planar portion and the curved portion.

17. The system as claimed in claim 11 wherein the wire having the shaped ball includes the shaped ball having a planar portion and a curved portion with a stepped portion between the planar portion and the curved portion.

18. The system as claimed in claim 11 wherein the wire having the shaped ball includes the shaped ball having a planar portion and a curved portion with a sloped portion between the planar portion and the curved portion.

19. The system as claimed in claim 11 further comprising wires each having a different shaped ball on the integrated circuit die.

20. The system as claimed in claim 11 further comprising a further wire having a further shaped ball with the further shaped ball on portion of the wire attached to the carrier.
